(19) United States
(12) Patent Application Publication
(10) Pub. No.: US 2004/0199855 A1
(43) Pub. Date: Oct. 7, 2004

(54) Copy-protected digital audio compact disc, and method and system for producing same

(76) Inventor: Richard A. A. Heylen, Yorkshire (GB)

Correspondence Address: PATENT DEPARTMENT, MACROVISION CORPORATION, 2830 DE LA CRUZ BLVD., SANTA CLARA, CA, 95050, US

(21) Appl. No.: 10/482,435

(22) PCT Filed: Mar. 21, 2002
(86) PCT No.: PCT/GB02/01360

(30) Foreign Application Priority Data
Jul. 3, 2001 (GB) 0116278.3

(51) Int. Cl. G11C 29/00

(52) U.S. Cl. 714/769

(57) ABSTRACT

In a system for protecting encoded digital data, for example, on a digital audio compact disc (CD-DA), specific audio samples are altered to cause spikes which are audible as clicks if played. All of the codewords in the encoded data which contain those altered samples are then identified, and data in each codeword is changed such that on decoding, the codewords will be identified as uncorrectable. Thus, if the decoded data is played by an audio player, error flags are reliably set so that error concealment, such as interpolation, is invoked and the spikes are inaudible. However, a data reader will either pass the uncorrectable data unchanged or will attempt to correct it. Therefore if a copy of the audio data is made, the clicks will be audible on playback.

The present invention relates to a method of copy protecting digital data and to copy protected media on which the digital data is stored.

Digital audio compact discs (CD-DA) which carry music or other audio can be played or read by more sophisticated apparatus, such as CD-ROM drives. This means, for example, that the data on a CD-DA acquired by a user may be read into a PC by way of its ROM drive and thus copied onto another disc or other recording medium. The increasing availability of recorders able to write to CDs is therefore an enormous threat to the music industry.

In an earlier proposed method, a digital audio compact disc is copy protected by rendering control data encoded onto the disc incorrect and/or inaccurate. The incorrect data encoded onto the CD is either inaccessible to, or not generally used by, a CD-DA player. Therefore, a legitimate audio CD bought by a user can be played normally on a compact disc music player. However, the incorrect data renders the CD unplayable by a CD-ROM drive.

However, as the audio compact disc is rendered unplayable on a CD-ROM drive, the user is also prevented from using the CD-ROM drive legitimately simply to play the music or other audio on the disc.

What is needed is a method of copy protection for a digital audio compact disc which, whilst preventing the production of usable copy discs, does not prevent or degrade the playing of protected audio discs on all players having the functionality to play audio discs.

WO 01/15028 discloses a method of copy protecting a CD-DA in which errors are introduced into the audio data itself. These errors are to be identified as ‘uncorrectable’ by the error correction arrangements normally provided in audio players or data readers. As a result, an audio player will conceal the errors, for example by substituting interpolated values for audio data identified as erroneous, whereas a data reader will either fail to read the erroneous data or will simply read the erroneous values. The uncorrectable errors on the CD-DA will, therefore, either render the protected CD-DA uncopiable, or they will add unacceptable noise when a copy of the protected CD-DA is played.

It has now become apparent that the scheme described in WO 01/15028 does not reliably produce errors which are recognised as ‘uncorrectable’. It is only when an audio player recognizes that there are errors in the audio data that it invokes error concealment, such as interpolation. Where there are errors, but interpolation, or other error concealment, is not used because of a failure to recognise its existence, the audio data reproduced will include the added errors. This is clearly not acceptable.

The present invention seeks to improve a copy protection scheme such as that described in WO 01/15028.

According to a first aspect of the present invention there is provided a method of copy protecting encoded digital data which can be successfully interpolated or subjected to error concealment after decoding for playback, the method comprising the steps of:

introducing altered values into the digital data, and

changing all codewords containing the introduced altered values such that, on decoding, the codewords will be identified as uncorrectable,

wherein each codeword is changed by adding to at least part of a value thereof, a value representative of an uncorrectable error identifying syndrome.

The use of a syndrome representative value to change each codeword provides for reliability on decoding in that irrespective of the values of the digital data, the change to each codeword will result in the codeword being identified as uncorrectable.

In a preferred embodiment, four bytes of each codeword are changed by addition with a syndrome representative value of four bytes. Preferably, all four bytes changed are parity values. Alternatively, it may be possible to add the syndrome representative value to just three or two bytes of the codeword. For CD-DAs, where a correcting code is generally at least two bytes, the syndrome representative value would normally be at least two bytes.

Preferably, the syndrome representative value is a coset leader representative of the syndrome.

In a preferred embodiment, the syndrome is one which is produced where an error locator polynomial generated in a decoder has no roots.

Whilst it was the intention of this invention to provide a method of copy protecting digital audio compact discs, it has become clear that the invention has utility for protecting any digital data where errors in the digital data are to be identified or corrected whilst accessing the data, and where any errors identified as uncorrectable will generally be interpolated, or otherwise concealed, during playback.

The copy protection method of the invention is arranged to identify codewords with altered values as uncorrectable. Where the digital data to be played, for example, is audio or visual images, or video, the player would generally be provided with error concealment means such as an interpolator. The identification, therefore, of codewords as uncorrectable is used to force the altered data values to be subject to interpolation or other concealment means during playback of the data.

However, a data reader does not utilise error concealment means when reading data, although it may use further decoding and error correction means to try to further correct the data. If, therefore, the encoded and copy protected digital data produced by a method of the invention is decoded by a digital reader and is flagged as uncorrectable, the data may be subject to additional attempts at correction and/or then the digital data, incorporating the altered values, is passed unchanged. If the data reader is being used as the input to a copier, for example, the altered values will be encoded onto the copy medium, such as a CD-DA. By this means, the copy produced will be degraded.

In a preferred embodiment of the invention, the altered values are made in digital audio data. This might be audio data, for example, to be encoded on to a CD-DA.

Preferably, the altered values are introduced by adding a large number to the audio data value. This can be done in the binary domain, for example, by adding a value in the range 128 to 143 to the MSB of an audio data value.

By XORing a large sample to the value already provided, it is not necessary to know what the original value of the audio data was, as the arithmetic will always guarantee that there is an audible spike produced on the audio data.

The present invention also extends to a medium on which copy protected encoded digital data, which can be successfully interpolated or subjected to error concealment after decoding for playback, has been stored, wherein the medium carries digital data into which altered values have been introduced, and codewords, containing the introduced altered values, which have been changed such that they will be identified as uncorrectable on decoding, wherein the codewords have each been changed by adding to at least part of a value thereof, a value representative of an uncorrectable error identifying syndrome.

Whilst the present invention finds particular application for the copy protection of, for example, CD-DAs, its ability to reliably produce an error flag may be used in other contexts, for example, for watermarking, or to provide a signature.

The invention also extends to a method of encoding digital data, the method comprising the steps of:

changing predetermined codewords generated from the digital data such that, on decoding, the codewords will be identified as uncorrectable,

wherein each codeword is changed by adding to at least part of a value thereof, a value representative of an uncorrectable error identifying syndrome.

The present invention also extends to a copy protection file arranged to alter digital data, and codewords produced therefrom, by methods as defined above.

Embodiments of the present invention will hereinafter be described, by way of example, with reference to the accompanying drawings, in which:

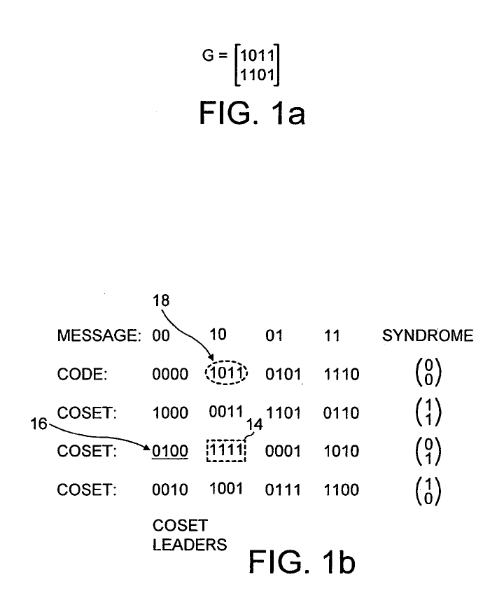

FIG. 1a shows a generator matrix for a code, and FIG. 1b shows a standard array generated by the operation of the generator matrix,

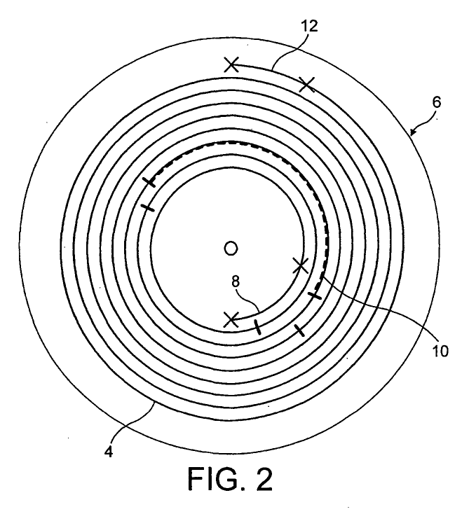

FIG. 2 shows schematically a CD,

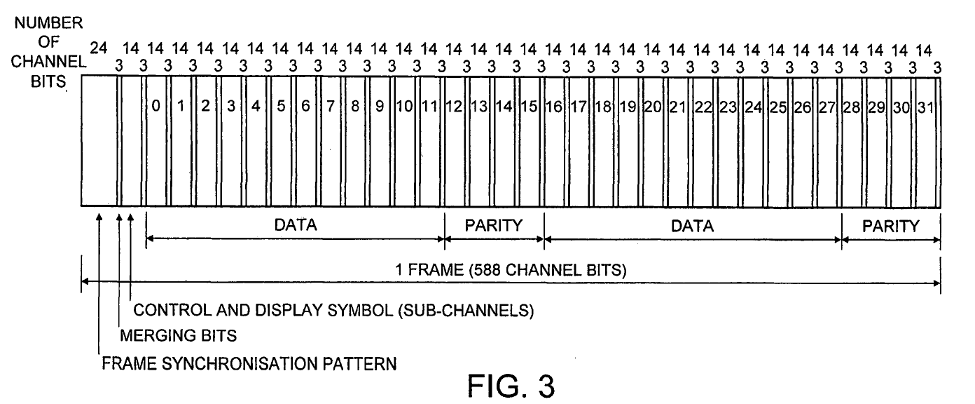

FIG. 3 shows the format of a frame of data on a CD,

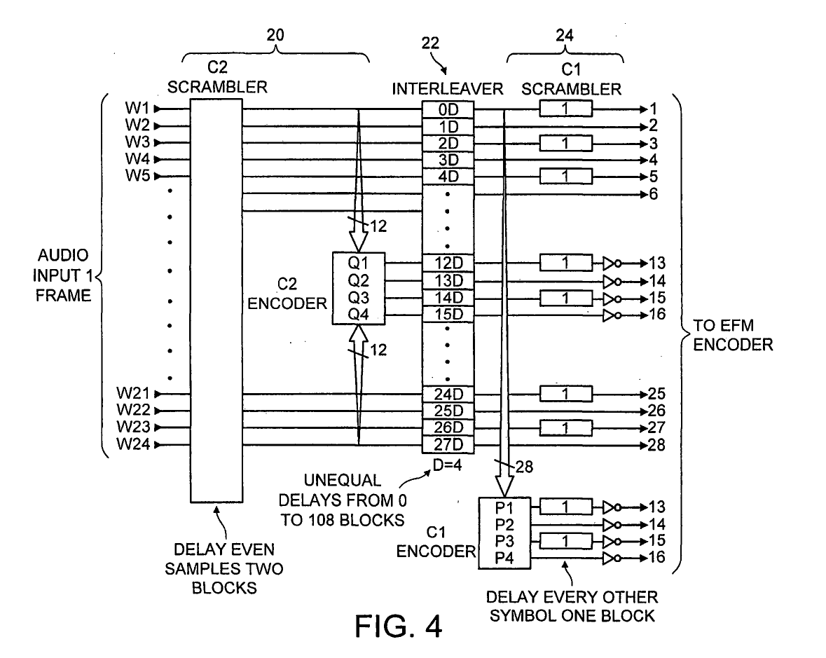

FIG. 4 shows schematically a CIRC encoder for data to be encoded on to a CD,

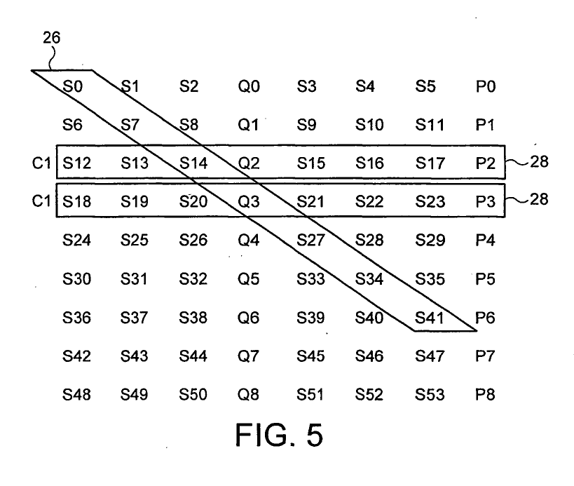

FIG. 5 shows a block of data after encoding,

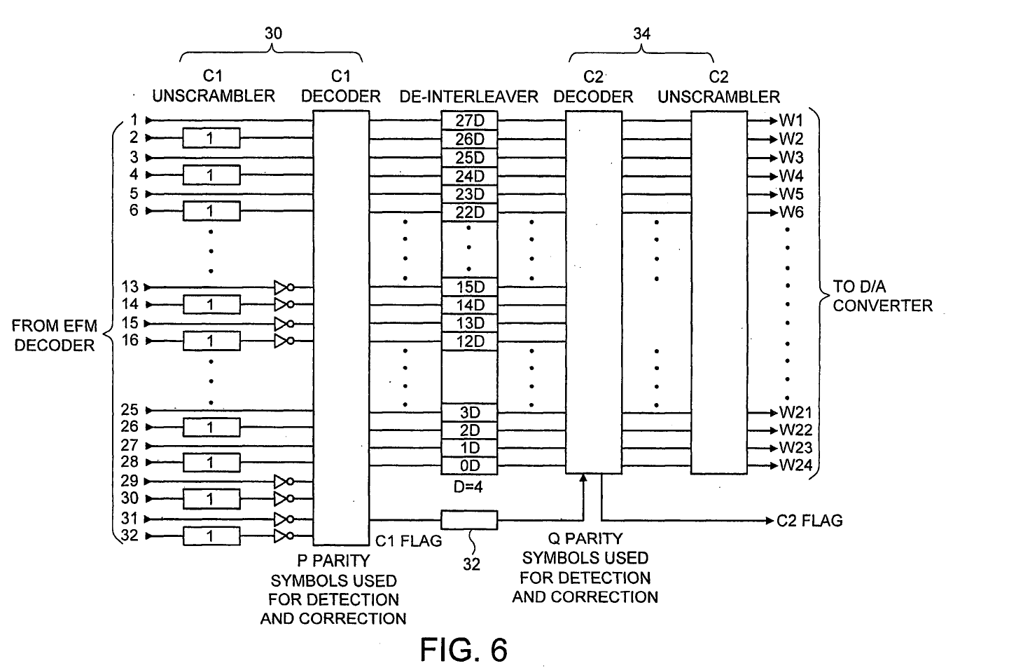

FIG. 6 shows a CIRC decoder,

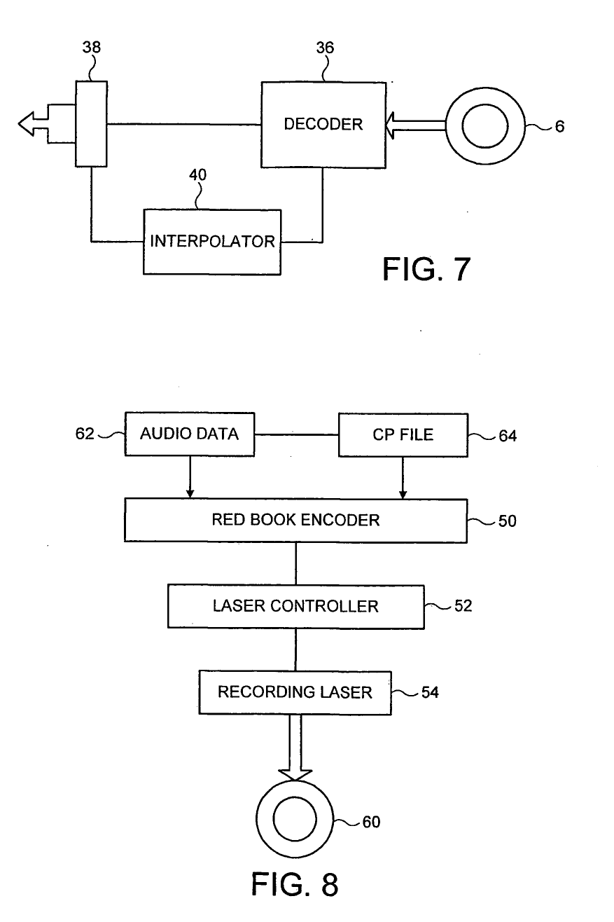

FIG. 7 shows schematically an audio player, and

FIG. 8 shows a circuit for applying a copy protection scheme of the invention to a CD,

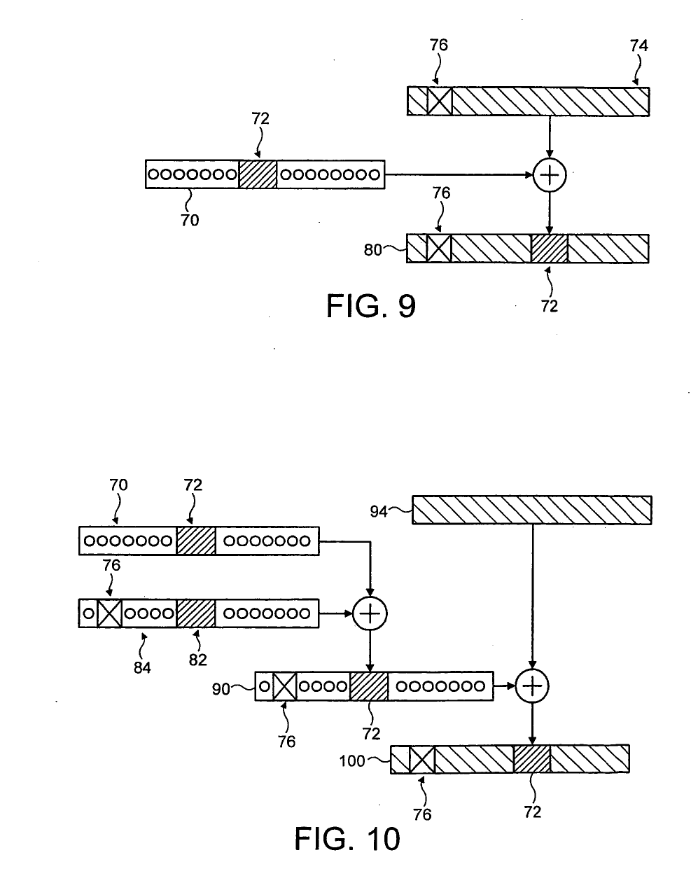

FIG. 9 shows schematically a method of associating a row of audio data with parity values which identify the row as uncorrectable, and

FIG. 10 shows schematically a further method of associating a row of audio data with parity values which identify the row as uncorrectable.

The practice of encoding digital data was developed to ensure that the correct information was received over early communications channels, such as the telegraph, despite noise. Now, however, digital data is routinely encoded to allow any errors in the data to be detected and corrected. In this respect, the basic methods of the invention described herein are described with particular reference to the encoding and decoding of data on CD-DAs. However, it will be appreciated that these methods are equally applicable in any context where there is digital data which is to be encoded, for example, for reliability, and where errors in the digital data are to be concealed, on playback, by interpolation or other error concealment techniques.

The theories of error correcting codes will be known to those skilled in the art, and are not presented here. However, some basic concepts are now explained, by way of example, to aid understanding.

CD-DAs, and indeed CD-ROMs and similar formats, utilise Reed-Solomon codes for encoding and error detection. Reed-Solomon codes are a subclass of BCH codes, whilst BCH codes are a generalisation of Hamming codes. Hamming codes are single error correcting codes, and are generalised in BCH codes which enable the correction of a number of errors.

We will look first at a simple linear, single error correcting (Hamming) code.

A message u, having k symbols, is encoded into a codeword or vector x, having n symbols, to produce a linear code. The first part of the codeword consists of the message itself, followed by n-k check symbols or parity values.

So, if the message is:

u=u₁ u₂ uₖ

the codeword is

x=X₁ x₂ . . . xₖ . . . xₙ

where n>k, and u₁=x₁, u₂=x₂, . . . uₖ=xₖ

The check symbols are chosen so that

$${Hx}^{tr} = H ( \begin{matrix}{x}_{1} \\ {x}_{2} \\ ⋮ \\ {x}_{n}\end{matrix} ) = O$$

where H is the parity check matrix of the code.

The arithmetic is performed modulo 2, or XOR, ie 0+1=1, 1+1=0, −1=+1.

To generate a code from a message, the message u is operated upon by a generator matrix G to form the codeword x, ie x=uG

The generator matrix G is related to the parity check matrix H and a set of independent codewords taken from a given code may be used as the rows of a generator matrix.

So, as indicated above, a message

u=u₁ u₂ . . . uₖ, becomes

codeword x=x₁ x₂ . . . xₖ . . . xₙ

On decoding, the system receives the

received vector y=y₁ y₂ yₖ . . . yₙ

The decoding system has to decide which words of the received vector y are correct, and thus codewords, and also, if there are errors, to correct them.

A useful way to decode a linear code is by utilising cosets. For an [n, k] linear code C as in the examples set out above, which will occupy a field with q elements, the set

a+C={a+x:xεC}

where a is any vector of the code C, is a coset of the code C. Each coset has q^{k} vectors.

FIG. 1a shows a generator matrix G for a [4, 2] code, ie. a code where k=2 and n=4, and FIG. 1b shows a standard array showing a message, the code C generated from the message by the operation of the generator matrix G, and the three cosets generated from the code C. The three coset words in the left hand column of the array have the smallest number of nonzero values of the vectors in each coset and thus have the minimum weight. These minimum weight vectors are the coset leaders.

When a word of the received vector y is received, its position in the standard array is identified. If it is found in one of the cosets, the appropriate coset leader is identified as the likely error whereby the word can be decoded.

Thus, for example, if the y value received is 1111 as shown at location 14, its position in the array is found and that location determines that the appropriate coset leader is 0100, as shown at 16. The illustrated array shows that the correct codeword 18 is 1011. During decoding, the codeword 18 can be determined as 1111−0100=1011. This method of decoding is maximum likelihood decoding.

The last column in the array illustrated in FIG. 1b shows the syndrome for each row of the array, which is defined as:

S=Hy^{tr}

and indicates the locations of errors. If there are no errors, the syndrome of y is 0. Furthermore, two vectors are in the same coset if they have the same syndrome. Basically, the syndrome contains all the information the receiver has about errors.

Of course, in practical systems, more than one error may occur and will need correcting. It would be possible to cope with this by increasing the number of check symbols, and hence by increasing the number of vectors in the parity check matrix H of the code and in the generator matrix G. However, to make the arithmetic more manageable each column of m binary vectors in the matrix, an m-tuple, is represented by an appropriate polynomial α. The generator matrix is replaced by a generator polynomial

g(x)=(x−α^{b})(x−α^{b}+1) . . . (x−α^{b+d2})

where b is a number, frequently 1.

The standard array then includes polynomials representing codewords, rather than the codes themselves. However, it is still arranged to have cosets, with coset leaders, and to have syndromes identifying error locations. Therefore, decoding is as described above, with reference to FIG. 1b, except that the m-tuples need to be mapped to provide the codes, and the polynomials for the m-tuples have to be solved as it is their roots which identify the error locations.

We will now look briefly at the encoding of digital data on CD-DAs and at the copy protection scheme described in WO 01/15028.

A digital audio compact disc (CD-DA), which carries music and is to be played on an audio player such as a conventional CD disc player, is made and recorded to a standard format known as the Red Book standards. As well as defining physical properties of the disc, such as its dimensions, and its optical properties, such as the laser wavelength, the Red Book also defines the signal format and the data encoding to be used.

As is well known, the use of the Red Book standards ensure that any CD-DA produced to those standards will play on any audio player produced to those standards.

FIG. 2 shows schematically the spiral track 4 on a CD 6. This spiral track 4 on a CD-DA is divided into a Lead-In 8, a number of successive music or audio tracks as 10, and a Lead-Out 12. The Lead-In track 8 includes a Table of Contents (TOC) which identifies for the player the tracks to follow, whilst the Lead-Out 12 gives notice that the spiral track 4 is to end.

An audio player always accesses the Lead-In track 8 on start up. The music tracks may then be played consecutively as the read head follows the track 4 from Lead-In to Lead-Out. Alternatively, the player navigates the read head to the beginning of each audio track 10 as required.

To the naked eye, a CD-ROM looks exactly the same as a CD-DA and has the same spiral track 4 divided into sectors. However, data readers, such as CD-ROM drives, are enabled to read data, and process information, from each sector of the compact disc according to the nature of that data or information. A data reader can navigate by reading information from each sector whereby the read head can be driven to access any appropriate part of the spiral track 4 as required.

To ensure that any data reader can read any CD-Rom, the compact discs and readers are also made to standards known, in this case, as the Yellow Book standards. These Yellow Book standards incorporate, but extend, the Red Book standards. Hence, a data reader, such as a CD-ROM drive, can be controlled to play a CD-DA.

The ability of a data reader to access, extract, or otherwise read the data on a CD-DA provides a problem for the music industry. A user can use his CD-ROM drive to read the data from an audio disc, for example, into a computer file, and then that data can be copied. The increasing availability of recorders able to record onto compact discs means that individuals and organisations now have easy access to technology for making perfect copies of audio compact discs. This is of great concern to the music industry.

As the data encoding on a CD-DA and on a CD-ROM is well known and in accordance with the appropriate standards, it is not necessary to describe it in detail herein.

Briefly, the data on a CD is encoded into frames by EFM (eight to fourteen modulation). FIG. 3 shows the format of a frame, and as is apparent therefrom, each frame has sync data, sub-code bits providing control and display symbols, data bits and parity bits. Each frame includes 24 bytes of data, which, for a CD-DA, is audio data.

There are 8 sub-code bits contained in every frame and designated as P, Q, R, S, T, U, V and W. Generally only the P and Q sub-code bits are used in the audio format. The standard requires that 98 of the frames of FIG. 3 are grouped into a sector, and the sub-code bits from the 98 frames are collected to form sub-code blocks. That is, each sub-code block is constructed a byte at a time from 98 successive frames. In this way, 8 different subchannels, P to W, are formed. These subchannels contain control data for the disc. The P- and Q-subchannels incorporate timing and navigation data for the tracks on the disc, and generally are the only subchannels utilised on an audio disc.

Before the data on a CD is subjected to EFM encoding and formed into the frame structure illustrated in FIG. 3, it is subjected to error correcting encoding. Specifically, the data to be stored on a CD is interleaved to distribute errors, and has parity values incorporated for error correction. The particular algorithm used in the compact disc system is the Cross Interleave Reed-Solomon Code (CIRC) and an example of the CIRC encoding scheme is shown in FIG. 4. As can be seen, a C2 encoder 20 accepts 24 bytes of audio data, subjects some bytes to delay, and produces four bytes of Q parity values. Cross interleaving by way of an interleaver 22 follows the C2 encoder 20 whereby the 28 bytes are delayed by different periods. As a result of this interleaving, each C2 word is stored in 28 different C1 codewords.

A C1 encoder 24 accepts a 28 byte vector containing data from 28 different C2 codewords, and produces 4 more bytes of P parity values. The resulting 32 byte codewords leave the CIRC encoder of FIG. 4 and are applied to the EFM encoder.

An example of a block of data produced by a CIRC encoder of FIG. 4 is illustrated in FIG. 5 where each S value represents 4 bytes of data, each Q value represents 4 bytes of Q parity values, and each P value represents 4 bytes of P parity values. In addition, FIG. 5 illustrates the data rows, as 26, which are subject to decoding by a C2 decoder, and the data rows, as 28, which are subject to decoding by a C1 decoder.

FIG. 6 shows schematically a CIRC decoder for decoding blocks of data from a CD. Thus, and as is known, the pits and lands on a CD are read and subject to EFM demodulation and are then applied to the CIRC decoder for de-interleaving, error detection and error correction. The data is input to the decoder in blocks as shown in FIG. 5 and is output as 24 bytes of audio data.

Thus, a frame of 32 8 bit words are applied to the decoder of FIG. 6. This frame of 32 bytes includes 24 bytes of audio data and 8 bytes of parity values. In a C1 decoder 30, errors are detected by the 4 P parity bytes and short duration random errors are corrected. Larger errors, for example, long burst errors, may result in a number of C1 rows being uncorrectable or having two correctable errors. These rows will be appropriately flagged. For example, advanced decoders may mark each erroneous row using erasure flags in the expectation that the errors can be corrected at the C2 stage. All words found to be valid are passed along unprocessed. Thus, the C1 decoder 30 flags any errors identified, but not corrected, as indicated at 32. A C2 decoder 34 passes all words without flags as error free if they also appear error free during C2 decoding. The C2 decoder 34 attempts to correct any remaining errors using the Q parity values and any error flags.

As indicated, during decoding the C1 rows are examined first to detect isolated errors and apply correction. C1 decoders are usually set to correct at most a single arbitrary erroneous symbol and therefore are able to detect error conditions in excess of this limit accurately, and to pass along error detection information, in the form of flags, to the C2 decoder 34. At the C2 decoder, a detected error within the error-correction limits results in the correction of the errors. However, a detected error in excess of the error-correction limits results in the generation of a C2 flag as indicated. A C2 flag signifies that an uncorrectable error has been detected.

FIG. 7 shows schematically an audio player. As can be seen, the data from a CD-DA 6 is passed to a Red Book decoder, indicated at 36, and then may be fed directly to a sound reproduction device 38. However, where an uncorrectable error has been detected and a C2 flag generated, the data is fed via an error concealment unit 40 to the sound reproduction unit 38.

The nature of the error concealment unit 40 provided in an audio player varies and may, for example, incorporate sound muting circuits. In the illustrated embodiment, the error concealment unit 40 has been shown as an interpolator 40.

It will be appreciated that an audio spectrum is generally continuous and that if an error produces a discontinuity in the spectrum, the missing value can, in most cases be readily, and fairly accurately, be interpolated. However, where a data reader, for example, is being used to access digital data, interpolation cannot be used as the value of one symbol has no relationship to the symbol which is next retrieved. This provides a method of copy protecting CA-DAs, which copy protection scheme will allow play of a CD by an audio player whilst preventing the use of a data reader to make a useable copy of the disc.

Basically, for copy protection, unwanted noise is incorporated in the audio data recorded on the disc and is associated with error correction words which identify the unwanted noise as uncorrectable and thereby cause the generation of a C2 flag as described above. Such data will be passed by an audio player to an interpolator, as 40, which is able to remove the unwanted noise and substitute a more appropriate audio value. However, a data reader will simply read the audio data, flagged as uncorrectable, so that the unwanted noise is written to disc, for example, during copying. The copy disc, therefore, is significantly degraded.

A method of copy protecting CD-DAs by flagging introduced, unwanted noise on a disc as uncorrectable is proposed in WO 01/15028. This specification proposes altering the audio data by the addition of ‘spikes’, and then changing the parity words associated with the C1 and C2 rows containing the changed audio data such that the altered audio data is identified, and flagged, as uncorrectable. Generally, the scheme proposed in WO 01/15028 is to replace C2 parity bytes with unused symbols and to replace C1 parity bytes with zeros.

However, different decoders use different algorithms with consequent differences in error correction performance. It has been found that some decoders ‘miscorrect’ the errors rather than flagging them as uncorrectable. It is also theoretically possible for C1 parity bytes to be zero so that setting them to zero leaves the C1 row unchanged.

With a copy protection scheme as proposed in which spikes are to be added to the audio data on a CD-DA to produce clicks it is imperative to ensure that all audio players are triggered to use their interpolators to remove the spikes no matter how sophisticated the decoder provided and irrespective of its methods of error correction. Clearly, the music industry will be unwilling to incorporate a copy protection technique if there is a realistic risk that the unwanted added noise will be audible when the consumer plays a genuine CD-DA on a typical consumer audio player.

We have seen above that in decoding, a syndrome can be calculated from the symbols in a received vector. In this respect, the calculations can be arranged so that each syndrome only contains information about how its associated row differs from a correct row. If the syndrome is all zero, this indicates that the row is free of errors and thus that the received vector is a codeword. Hence, no error correction of the received vector is required. For a copy protection scheme of the invention, it is important that a decoder will treat a row in accordance with its syndrome regardless of the value of the data symbols in the row. Thus, and as set out above, if the syndrome shows the row to be correct, its data can be passed unchanged. Similarly, if the syndrome shows that the data is uncorrectable, the decoder will pass the row with an error flag set.

Thus, in the method of the invention a row of code will be passed uncorrected, but with an error flag set, if the syndrome associated with the row tells the decoder that the data in the row is uncorrectable. Therefore, it is necessary to find a syndrome, either experimentally or mathematically, which will always prevent the decoder from correcting the associated row.

There are a number of common ways in which a decoding algorithm can fail such that an error flag is set. The most common way for the decoding algorithm to fail is where the error locator polynomial of the associated row has no roots. In a preferred embodiment of the invention, therefore, a syndrome is chosen which indicates that the error locator polynomial has no roots.

Of course, there is the difficulty that the syndrome is generated by the decoder and thus that data has to be encoded onto the disc which will reliably cause the syndrome to be generated for C1 or C2 rows of data containing the altered audio values. Furthermore, this ‘syndrome generating data’ will not be encoded on to the disc in isolation but together with the audio data carried by the disc and control and coding data.

In encoding and decoding, vectors are added in modulo 2 arithmetic, in which the bytes are XORed together. With the invention, therefore, one or more symbols in a codeword are XORed with one or more chosen symbols. The symbols are chosen such that the decoding of a codeword containing the chosen symbols will generate the determined syndrome. Specifically, the vector of the chosen symbols is the coset leader from one of the cosets which gives the syndrome required. It has been found that XORing data values with this representative of the required syndrome reliably causes a decoder to flag an error irrespective of the data in the codeword concerned.

It would, of course, be possible to use this method of reliably obtaining an error flag from the decoder for watermarking a disc, or protecting it by way of an added signature. In watermarking, specific descriptive data is added to the disc to enable a copy to be distinguished from an original.

However, the present invention finds particular use with copy protection where specific audio samples are to be altered to cause spikes which are audible as clicks if played. An example of this is shown, for example, in WO is 01/15028 where impulses are superimposed on particular samples of the correct audio data to produce spikes therein.

Thus, with the invention, one or more samples of the audio may be changed, as required, to degrade the audio content. For example, this might be by the superimposition of impulses as described in WO 01/15028. All of the codewords which contain those altered samples are then identified and data in each of those codewords is changed by XORing bytes thereof with the coset leader value.

Generally four bytes of each codeword are changed by XORing with the four byte coset leader.

In the preferred embodiment, and as illustrated in FIG. 9, the four bytes changed correspond to the parity bytes. Thus, all of the values in the chosen coset leader 70, which will act as a corrupting row, will be zero, except for the values in locations 72 corresponding to the parity bytes. It has been determined that if all four parity bytes are given non-zero values then the row generated therefrom will be reliably flagged as uncorrectable. Depending upon the coset, it may or may not be possible to find a coset leader with three, two or one non-zero elements.

FIG. 9 illustrates schematically a method of the invention in which a row 74 of audio data incorporating an audible click 76 is associated with an error correction word 70 which identifies the row 74 as uncorrectable. The row 74 incorporating the audible click 76 is XORed at 78 with the coset leader 70 to produce the row 80 which incorporates the click 76 and the corrupting parity bytes 72. Thus, although the row 80 is a codeword containing correct audio data, it is identified as uncorrectable by the presence of the corrupting parity bytes 72.

It would be possible, of course, to determine just a single coset leader, as 70, and to use that to change all of the codewords on a CD-DA containing degraded audio data. However, it is presently thought that the syndrome and its coset leader would not be used over the whole of one disc, but that various syndromes would be utilised.

Whilst the audio data can be changed, as described in WO 01/15028, it is also possible to only render the most significant byte (MSB) of the sample uncorrectable.

Thus, in a preferred embodiment, one value in the range 128 to 143 inclusive is XORed with the most significant byte of an audio value to produce an altered data sample as 76 in FIG. 9. These altered data samples would be heard as clicks if they were to be played. However, upon decoding of a row 80 in an audio player, error flags will reliably be set invoking interpolation, or other error concealment, of those samples. However, a data reader will either pass the uncorrectable data unchanged or will attempt to correct it. If the data read by the data reader is then copied onto a disc, the clicks will be audible on playback whereby the copy disc is degraded.

As the audio symbols are altered by XORing, it is relatively easy to alter the value of the byte which is added to the most significant byte concerned. If the number is pseudo randomised, for example, the MSB of each sample can be XORed unpredictably with a byte, for example, having a value in the range 128 to 143.

This means that the magnitude of an imposed spike is not consistent so that it is less easy for those trying to ‘clean up’ a copy to recognise and remove the added spikes.

FIG. 9 illustrates one method of associating a codeword 74, with altered audio values, with a coset leader 70 whereby a codeword 80 flagged as uncorrectable is produced. However, there can be difficulties in practice in ensuring reliable association between a codeword as 74 with a coset leader as 70. Any such difficulties which may arise can be avoided by the use of the method which is illustrated schematically in FIG. 10.

As shown in FIG. 10, a coset leader 70 with corrupting parity bytes 72 is XORed with a created codeword 84. The created codeword 84 has been created from a vector containing all zeros except for one MSB in the relevant location. Parity bytes 82 of the codeword 84 confirm that the audio data of the created codeword is correct. The coset leader 90 produced by XORing 70 and 84 incorporates the click 76 from codeword 84 and the corrupting parity bytes 72 from the coset leader 70. Thus, the coset leader 90 shows the dick 76 to be uncorrectable. If the coset leader 90 is then XORed with a codeword 94 from an audio data source in which it is required to incorporate a click, the resulting row 100 will contain the audio data required, namely the audio data from row 94 with the click 76, but it will be flagged as uncorrectable by the existence of the parity bytes 72.

FIG. 8 shows a system for copy protecting an audio compact disc. As is conventional, a Red Book encoder 50 receives incoming data for encoding and application, by way of a laser controller 52 and a recording laser 54, on to a master disc 60. Generally, the data fed to the Red Book encoder 50 will be audio data from a source 62. However, with the invention, the modifications to the data as discussed above are caused by the copy protection software which is fed from a copy protection file source 64 to the Red Book encoder 50 in tandem with the audio data 62. This system is particularly useful for use with the method shown schematically in FIG. 10 as selected rows 94 of audio data 62 read from the source 62 can be XORed with created coset leaders as 90.

It will be appreciated that variations and modifications may be made to the embodiment described and illustrated in accordance with the present invention.

1. A method of copy protecting encoded digital data which can be successfully interpolated or subjected to error concealment after decoding for playback, the method comprising the steps of:
introducing altered values into the digital data, and
changing all codewords containing the introduced altered values such that, on decoding, the codewords will be identified as uncorrectable,
wherein each codeword is changed by adding to at least part of a value thereof, a value representative of an uncorrectable error identifying syndrome.

2. A method as claimed in claim 1, wherein four bytes of each codeword are changed by addition with a syndrome representative value of four bytes.

3. A method as claimed in claim 2, wherein all four bytes changed are parity values.

4. A method as claimed in claim 1, for use with a correcting code of at least two bytes, wherein the syndrome representative value is at least two bytes.

5. A method as claimed in any preceding claim, wherein the syndrome representative value is a coset leader representative of the syndrome.

6. A method as claimed in any preceding claim, wherein the syndrome is one which is produced where an error locator polynomial generated in a decoder has no roots.

7. A method as claimed in any preceding claim, arranged to protect digital data to be played, such as audio or visual images, or video, wherein a digital data player is provided with error concealment means, the method comprising the step of using the identification of codewords as uncorrectable to force the altered data values to be subject to the error concealment means during playback of the data.

8. A method as claimed in any preceding claim, wherein the altered values are made in digital audio data.

9. A method as claimed in claim 8, wherein the altered values are introduced by adding a large number to the audio data value.

10. A method as claimed in claim 9, wherein the large number is added to the audio data value in the binary domain by adding a value in the range 128 to 143 to the MSB of an audio data value.

11. A method of encoding digital data, the method comprising the steps of:
changing predetermined codewords generated from the digital data such that, on decoding, the codewords will be identified as uncorrectable,
wherein each codeword is changed by adding to at least part of a value thereof, a value representative of an uncorrectable error identifying syndrome.

12. A copy protection file arranged to alter digital data, and codewords produced therefrom, by a method as claimed in any of claims 1 to 11.

13. A medium on which copy protected encoded digital data, which can be successfully interpolated or subjected to error concealment after decoding for playback, has been stored, wherein the medium carries digital data into which altered values have been introduced, and codewords, containing the introduced altered values, which have been changed such that they will be identified as uncorrectable on decoding, wherein the codewords have each been changed by adding to at least part of a value thereof, a value representative of an uncorrectable error identifying syndrome.

14. A method of copy protecting encoded digital data substantially as hereinbefore described with reference to the accompanying drawings.

15. A method of encoding digital data substantially as hereinbefore described with reference to the accompanying drawings.

16. A copy protection file arranged to alter digital data, and codewords produced therefrom, substantially as hereinbefore described with reference to the accompanying drawings.

17. A medium on which copy protected encoded digital data has been stored substantially as hereinbefore described with reference to the accompanying drawings.
